(19) United States
(12) Patent Application Publication
(10) Pub. No.: US 2024/0314972 A1
(43) Pub. Date: Sep. 19, 2024

(54) HYBRID COOLING ARRANGEMENT FOR AUTONOMOUS AND IMMERSION COOLED RACKS

(71) Applicant: OVH, Roubaix (FR)

(72) Inventors: Mohamad HNAYNO, Roubaix (FR); Ali CHEHADE, Moncheaux (FR)

(21) Appl. No.: 18/588,745

(22) Filed: Feb. 27, 2024

(30) Foreign Application Priority Data
Mar. 16, 2023 (EP) 23305366.9

(51) Int. Cl. H05K 7/20

(52) U.S. Cl. CPC H05K 7/20236; H05K 7/20263; H05K 7/20272; H05K 7/20781

(57) ABSTRACT

A rack assembly including a cooling module for liquid-to-liquid cooling, a rack and an immersion cooling (IC) rack. The rack includes a rack cooling block that cools a rack electronic processing assembly and a rack fluid conduit that circulates a first cooling fluid through the rack cooling block and the cooling module. The IC rack includes a dielectric IC fluid, an IC cooling block immersed in the dielectric IC fluid for cooling an IC electronic processing assembly when the IC electronic processing assembly is placed in contact with the IC cooling block and an IC fluid conduit that circulates a second cooling fluid through the IC cooling block and the cooling module. The rack and the IC rack are thermally connected via the cooling module such that thermal energy can be transferred between the IC fluid conduit and the rack fluid conduit within the cooling module.

### CROSS REFERENCE

The present application claims priority to EP application Ser. No. 23/305,366.9, filed Mar. 16, 2023, entitled “HYBRID COOLING ARRANGEMENT FOR AUTONOMOUS AND IMMERSION COOLED RACKS”, the entirety of which is incorporated herein by reference.

### FIELD OF TECHNOLOGY

The present technology generally relates to cooling techniques of electronic equipment rack assemblies within datacenters. In particular, a hybrid cooling arrangement to service forced air, liquid block cooling of rack assemblies, and immersion cooling rack assemblies is presented.

### BACKGROUND

Datacenters house many rack-mounted electronic computing equipment, such as servers, processors, etc. In use, electronic processing assemblies generate a significant amount of heat that must be quelled or at least dissipated in order avoid electronic component failures and ensure continued efficient operation.

Various measures have been implemented to address the dissipation of heat generated by the electronic assemblies. A first being an autonomous rack configuration which implements forced-air ventilation and direct liquid block cooling techniques for cooling one or more heat-generating processing assemblies. The autonomous rack configuration includes a first cooling loop and a second cooling loop which are thermally connected by a liquid-to-liquid heat exchanger. Specifically, the first cooling loop contains a first heat transfer liquid conveyed to a plurality of liquid cooling blocks which are arranged in direct thermal contact with heat generating electronic processing assemblies. The first heat transfer liquid collects thermal energy from the electronic processing assemblies and is directed to a first side of the liquid-to-liquid heat exchanger. The second cooling loop contains a second heat transfer liquid which is directed to an air-to-liquid heat exchanger. The air-to-liquid heat exchanger transfers the thermal energy from the ambient air to the second heat transfer liquid which is then directed to the liquid-to-liquid heat exchanger. Within the liquid-to-liquid heat exchanger, thermal energy is transferred from the first heat transfer liquid to the second heat transfer liquid. In other words, there is a transfer of heat from the first cooling loop, which has a higher temperature, to the second cooling loop.

A second measure implemented to address the heat generated by the electronic processing assemblies involves immersive cooling (IC) racks. An IC rack includes an immersion case containing a dielectric immersion cooling fluid in which one or more electronic processing assemblies and a serpentine convection coil are submerged. A cooling fluid is directed through the serpentine convention coil to reduce the ambient temperature of the dielectric cooling fluid within the immersion casing. The cooling fluid is then directed towards the electronic processing assemblies. Similar to the autonomous rack, IC racks implements liquid cooling blocks in direct thermal contact with the electronic processing assemblies such that thermal energy is transferred from the electronic processing assemblies to the cooling fluid to reduce the temperature of the electronic processing assemblies. The now warm cooling fluid is then directed through an outlet.

There is thus an interest in developing a hybrid cooling arrangement.

### SUMMARY

The embodiments of the present disclosure are based on developers' understanding of the drawbacks associated with conventional autonomous rack and immersive cooling systems for cooling electronic assemblies containing heat-generating components. The present disclosure provides a hybrid cooling arrangement in which an autonomous rack configuration and IC rack configuration are thermally connected while remaining fluidly isolated, thus providing efficient heat dissipation of the electronic processing assemblies of each system.

According to one aspect of the present technology, there is provided a rack assembly including a cooling module for liquid-to-liquid cooling, a rack and an immersion cooling (IC) rack. The rack includes a rack cooling block configured to cool a rack electronic processing assembly when the rack electronic processing assembly is placed in contact with the rack cooling block and a rack fluid conduit configured to circulate a first cooling fluid through the rack cooling block and the cooling module. The immersion cooling (IC) rack includes a dielectric immersion cooling fluid, an IC cooling block immersed in the dielectric immersion cooling fluid and configured to cool an IC electronic processing assembly when the IC electronic processing assembly is placed in contact with the IC cooling block and an IC fluid conduit for circulating a second cooling fluid through the IC cooling block and the cooling module. The rack and the immersion cooling rack are thermally connected via the cooling module such that thermal energy can be transferred between the IC fluid conduit and the rack fluid conduit within the cooling module.

In some embodiments of the present technology, the IC rack further includes a plurality of immersion casings fluidly connected in parallel with one another and configured to house the dielectric immersion cooling fluid. The IC cooling block includes a plurality of IC cooling blocks. Each of the plurality of IC cooling blocks are housed within each of the plurality of immersion casings.

In some embodiments of the present technology, the IC rack further includes a plurality of IC racks immersion casings fluidly connected in series with one another and configured to house the dielectric immersion cooling fluid. The IC cooling block includes a plurality of IC cooling blocks. Each of the plurality of IC cooling blocks are housed within each of the plurality of immersion casings.

In some embodiments of the present technology, the rack further includes an air-to-liquid heat exchanger configured to receive the first cooling fluid via the rack fluid conduit such that thermal energy of the first cooling fluid is transferred to ambient air.

In some embodiments of the present technology, the air-to-liquid heat exchanger includes three air-to-liquid heat exchangers fluidly connected in series to one another, or three air-to-liquid heat exchangers fluidly connected in parallel to one another.

In some embodiments of the present technology, a temperature of the first cooling fluid prior to flowing through the air-to-liquid heat exchanger is 27° C.

In some embodiments of the present technology, a temperature of the first cooling fluid after exiting the air-to-liquid heat exchanger is greater than 30° C.

In some embodiments of the present technology, the temperature of the first cooling fluid after exiting the air-to-liquid heat exchanger is 35° C.

In some embodiments of the present technology, the cooling module includes a cooling module pump and a liquid-to-liquid heat exchanger, wherein the cooling module pump is fluidly connected in series to the liquid-to-liquid heat exchanger.

In some embodiments of the present technology, the rack cooling block is fluidly connected downstream from the cooling module, or wherein the rack cooling block is fluidly connected upstream from the cooling module.

In some embodiments of the present technology, the rack fluid conduit and the IC fluid conduit are fluidly isolated from one another.

In some embodiments of the present technology, thermal energy is transferred from the IC fluid conduit to the rack fluid conduit within the cooling module.

In some embodiments of the present technology, the cooling module includes two cooling modules fluidly connected in parallel to one another.

In some embodiments of the present technology, the rack includes a plurality of racks fluidly connected in parallel with one another.

In some embodiments of the present technology, the rack includes a plurality of racks fluidly connected in series with one another.

In some embodiments of the present technology, the rack is assembled with the cooling module.

In some embodiments of the present technology, the rack further includes the rack electronic processing assembly, and wherein the IC rack further comprises the IC electronic processing assembly.

In some embodiments of the present technology, the at least one immersion casing includes a serpentine coil submerged in the dielectric fluid and fluidly connected to the second fluid conduit.

In some embodiments of the present technology, the rack fluid circuit includes an inlet and an outlet and wherein a temperature difference of the first cooling fluid between the inlet and the outlet is greater than 20° C.

In some embodiments of the present technology, the temperature difference of the first cooling fluid between the inlet and the outlet is 35° C.

In some embodiments of the present technology, a temperature of the first cooling fluid upstream from the cooling module is higher than a temperature of the first cooling fluid downstream from the cooling module.

In some embodiments of the present technology, a temperature of the second cooling fluid upstream from the cooling module is lower than a temperature of the second cooling fluid downstream from the cooling module.

In some embodiments of the present technology, a temperature of the first cooling fluid after exiting the cooling module is 47° C.

In some embodiments of the present technology, a temperature of the second cooling fluid prior to entering the cooling module is 43° C.

In some embodiments of the present technology, a temperature of the second cooling fluid after exiting the cooling module is 55° C.

In some embodiments of the present technology, a temperature of the first cooling fluid after exiting the rack electronic processing assembly is 62° C.

In some embodiments of the present technology, the rack assembly further includes at least one rack solenoid valve positioned on the rack fluid conduit.

In some embodiments of the present technology, the rack assembly further includes at least one IC rack solenoid valve positioned on the IC fluid conduit.

In some embodiments of the present technology, the IC rack further includes a cooling device.

In some embodiments of the present technology, the rack further comprises a plurality of racks, each rack comprising a distinct rack cooling block and a distinct air-to-liquid heat exchanger and wherein the distinct rack cooling blocks are connected in series with one another and the distinct air-to-liquid heat exchangers are connected in series with one another.

In some embodiments of the present technology, the rack further includes a plurality of racks, each rack comprising a distinct rack cooling block and a distinct air-to-liquid heat exchanger and wherein the distinct rack cooling blocks are connected in parallel with one another and the distinct air-to-liquid heat exchangers are connected in parallel with one another.

In the context of the present specification, unless expressly provided otherwise, electronic equipment may refer, but is not limited to, “servers”, “electronic devices”, “operation systems”, “systems”, “computer-based systems”, “controller units”, “monitoring devices”, “control devices” and/or any combination thereof appropriate to the relevant task at hand.

In the context of the present specification, unless expressly provided otherwise, the words “first”, “second”, “third”, etc. have been used as adjectives only for the purpose of allowing for distinction between the nouns that they modify from one another, and not for the purpose of describing any particular relationship between those nouns.

It must be noted that, as used in this specification and the appended claims, the singular form “a”, “an” and “the” include plural referents unless the context clearly dictates otherwise.

As used herein, the term “about” in the context of a given value or range refers to a value or range that is within 20%, preferably within 10%, and more preferably within 5% of the given value or range.

As used herein, the term “and/or” is to be taken as specific disclosure of each of the two specified features or components with or without the other. For example “A and/or B” is to be taken as specific disclosure of each of (i) A, (ii) B and (iii) A and B, just as if each is set out individually herein.

Embodiments of the present technology each have at least one of the above-mentioned object and/or aspects, but do not necessarily have all of them. It should be understood that some aspects of the present technology that have resulted from attempting to attain the above-mentioned object may not satisfy this object and/or may satisfy other objects not specifically recited herein.

Additional and/or alternative features, aspects, and advantages of embodiments of the present technology will become apparent from the following description, the accompanying drawings, and the appended claims.

### BRIEF DESCRIPTION OF THE DRAWINGS

For a better understanding of the present technology, as well as other aspects and further features thereof, reference is made to the following description which is to be used in conjunction with the accompanying drawings, where:

FIG. 1 illustrates a functional block diagram of a hybrid cooling arrangement servicing autonomous rack and immersion cooling rack configurations within a rack assembly, in accordance with the embodiments of the present disclosure;

FIG. 2 illustrates a functional block diagram of an alternative hybrid cooling arrangement servicing autonomous rack and immersion cooling rack configurations within a rack assembly, in accordance with the embodiments of the present disclosure;

FIG. 3 illustrates a functional block diagram of another alternative hybrid cooling arrangement servicing autonomous rack and immersion cooling rack configurations within a rack assembly, in accordance with the embodiments of the present disclosure; and,

FIG. 4 illustrates a functional block diagram of yet another alternative hybrid cooling arrangement servicing autonomous rack and immersion cooling rack configurations within a rack assembly, in accordance with the embodiments of the present disclosure.

It should be noted that, unless otherwise explicitly specified herein, the drawings are not to scale.

### DETAILED DESCRIPTION

The examples and conditional language recited herein are principally intended to aid the reader in understanding the principles of the present technology and not to limit its scope to such specifically recited examples and conditions. It will be appreciated that those skilled in the art may devise various arrangements that, although not explicitly described or shown herein, nonetheless embody the principles of the present technology.

Furthermore, as an aid to understanding, the following description may describe relatively simplified implementations of the present technology. As persons skilled in the art would understand, various implementations of the present technology may be of a greater complexity.

In some cases, what are believed to be helpful examples of modifications to the present technology may also be set forth. This is done merely as an aid to understanding, and, again, not to define the scope or set forth the bounds of the present technology. These modifications are not an exhaustive list, and a person skilled in the art may make other modifications while nonetheless remain within the scope of the present technology. Further, where not examples of modifications have been set forth, it should not be interpreted that no modifications are possible and/or that what is described is the sole manner of implementing that element of the present technology.

Moreover, all statements herein reciting principles, aspects, and implementations of the present technology, as well as specific examples thereof, are intended to encompass both structural and functional equivalents thereof, whether they are currently known or developed in the future.

Aspects of the inventive concepts provided by the embodiments of the present disclosure are directed to a hybrid cooling arrangement capable of supporting the cooling needs of combined forced air and liquid block cooling configurations with immersive cooling configurations that coexist in datacenter rack assemblies.

Although the configurations of an autonomous cooling rack and an IC rack differ, there are certain features and different temperature tolerances which can be exploited to provide a hybrid cooling arrangement which can efficiently support both configurations within a datacenter rack assembly.

Furthermore, the developers have empirically observed that the internally channeled cooling liquid of the IC rack configurations are less temperature sensitive due to the use of dielectric immersion cooling fluids. As such, the IC rack configurations are capable of tolerating, and operating with, higher temperature channeled cooling liquids.

With these fundamental principles in place, we will now consider some non-limiting examples to illustrate various implementations of aspects of the present disclosure.

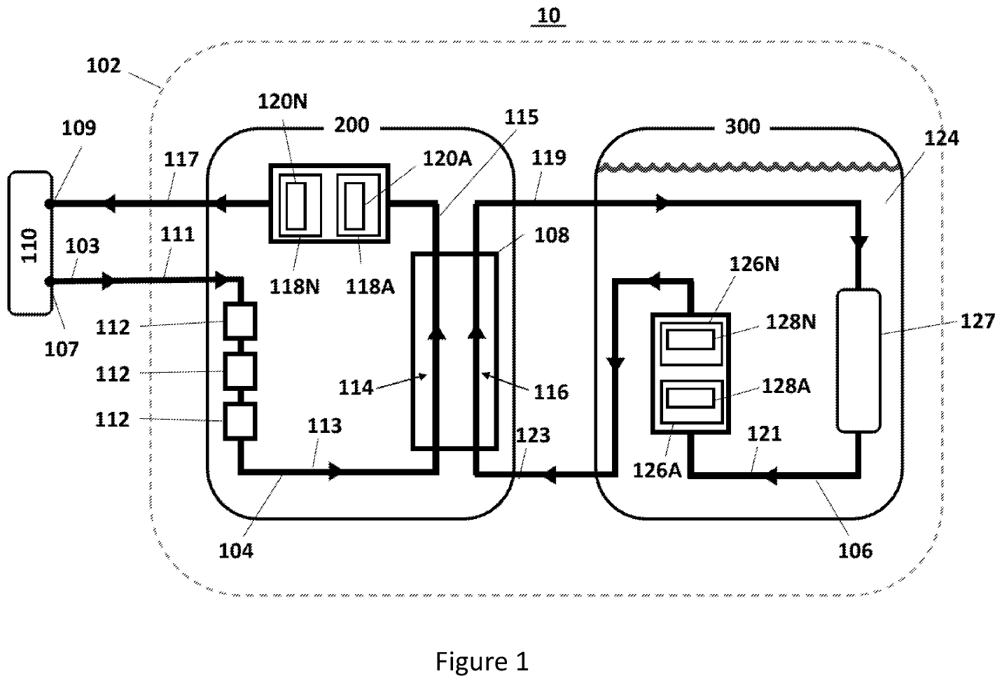

With reference to FIG. 1, a functional block diagram of a hybrid cooling arrangement 10 is depicted. The hybrid cooling arrangement 10 is configured to service representative autonomous racks 200 and immersion cooling (IC) racks 300 within a datacenter rack assembly 102, with the autonomous rack 200 and IC rack 300 configurations being fluidly isolated from one another. In other words, the autonomous rack 200 includes a rack fluid conduit 103 forming a first cooling circuit 104 and the IC rack 300 includes an IC fluid conduit 105 forming a second cooling circuit 106. The first cooling circuit 104 and second cooling circuit 106 are not fluidly connected to one another. The hybrid cooling arrangement 10 is configured such that the first cooling circuit 104 and second cooling circuit 106 are thermally connected via at least one cooling module 108 for liquid-to-liquid cooling such that thermal energy can be transferred between the rack fluid conduit 103 of the first cooling circuit 104 of the autonomous rack 200 and the IC fluid conduit 105 of the second cooling circuit 106 of the IC rack 300.

The autonomous rack 200 serviced by the hybrid cooling arrangement 10, receives a rack cooling fluid from a liquid cooling source 110. The rack cooling fluid may be a dielectric liquid or a non-dielectric liquid, for example and without limitation, water, glycol, oil, or a combination thereof. A cool rack cooling fluid 111 is supplied to the rack fluid conduit 103 via an inlet 107. The cool rack cooling fluid 111 is circulated through the rack fluid conduit 103 and is returned to the liquid cooling source 110 via an outlet 109, forming the first cooling circuit 104. In this embodiment, the liquid cooling source 110 is a facility or the datacenter and the cool rack cooling fluid 111 is water.

The autonomous rack 200 includes at least one air-to-liquid heat exchanger 112. In some embodiments, the at least one air-to-liquid heat exchanger 112 is equipped with a forced air ventilation fan. The at least one air-to-liquid heat exchanger 112 may include a rear door heat exchanger having a plate of multiple fans and a finned heat exchanger. For example, the fan plate and finned heat exchanger may be mounted on distinct hinges to allow for the opening of the finned heat exchanger while still enabling the fans to pull air. Alternatively, the fan plate may be mounted on hinges while the finned heat exchanger can be positioned on ergots.

The at least one air-to-liquid heat exchanger 112 includes internal fluid conduits (not shown) configured to receive the cool rack cooling fluid 111 and circulate the cool rack cooling fluid 111 throughout the at least one air-to-liquid heat exchanger 112. Ambient air is pulled into the at least one air-to-liquid heat exchanger 112 and the thermal energy of the ambient air is transferred to the cool rack cooling fluid 111, resulting in cool air being expelled. Due to the transfer of thermal energy to the cool rack cooling fluid 111, the cool rack cooling fluid 111 increases in temperature and may be referred to, in its increased temperature state, as “warm rack cooling fluid 113”.

In this embodiment, the at least one air-to-liquid heat exchanger 112 comprises three air-to-liquid heat exchangers 112 which are fluidly connected in series with one another.

The warm rack cooling fluid 113 is directed from the at least one air-to-liquid heat exchanger 112 to the at least one cooling module 108 for liquid-to-liquid cooling. The at least one cooling module 108 thermally connects the autonomous rack 200 with the IC rack 300 such that thermally energy is transferred between the rack fluid conduit 103 of the first cooling circuit 104 and the IC fluid conduit 105 of the second cooling circuit 106. In other words, thermal energy is transferred between the rack cooling fluid and an IC rack cooling fluid. More specifically, the warm rack cooling fluid 113 flows through a first side 114 while the IC rack cooling fluid flows through a second side 116 of the at least one cooling module 108. Each of the first side 114 and the second side 116 of the at least one cooling module 108 include internal conduits (not shown) configured to receive the respective fluids of the autonomous rack 200 and IC rack 300. In certain embodiments, the temperature of the IC rack cooling fluid is higher than that of the warm rack cooling fluid 113, as such, thermal energy of the IC rack cooling fluid is transferred to the warm rack cooling fluid 113 within the at least one cooling module 108, cooling the IC rack cooling fluid. The transfer of thermal energy to the warm rack cooling fluid 113 raises the temperature of the warm rack cooling fluid 113 which may further be referred to as “warmer rack cooling fluid 115”.

As depicted in FIG. 1, in this embodiment, the at least one cooling module 108 is assembled with the autonomous rack 200. The at least one cooling module 108 includes at least one pump and at least one plate heat exchanger, such that the at least one pump is fluidly connected in series with the at least one plate heat exchanger. In one embodiment, the at least one cooling module 108 includes two cooling modules fluidly connected in parallel with one another. In a specific example, the two cooling modules may be mini water-cooling modules.

The warmer rack cooling fluid 115 is directed from the at least one cooling module 108 and forwarded to one or more liquid cooling blocks 118A-118N. The one or more liquid cooling blocks 118A-118N are in direct thermal contact with corresponding electronic processing assemblies 120A-120N. Each of the one or more liquid cooling blocks 118A-118N include an internal fluid conduit (not shown) for directing the warmer rack cooling fluid 115 through the one or more liquid cooling blocks 118A-118N. It is contemplated that there may be a plurality of the one or more liquid cooling blocks 118A-118N and one or more electronic processing assemblies 120A-120N arrangements which may be fluidly connected in series or, fluidly connected in parallel, or a combination thereof (not shown).

The warmer rack cooling fluid 115 flows through the one or more liquid cooling blocks 118A-118N, in which thermal energy is transferred from the one or more electronic processing assemblies 120A-120N to the warmer rack cooling fluid 115, thus cooling the one or more electronic processing assemblies 120A-120N. As a result, the temperature of the warmer rack cooling fluid 115 is raised which may further be referred to as “warmest rack cooling fluid 117”.

The warmest rack cooling fluid 117 is directed from the arrangement of the one or more liquid cooling blocks 118A-118N and one or more electronic processing assemblies 120A-120N and returned to the liquid cooling source 110 via the outlet 109.

Exemplary temperatures along the fluid flow path of the autonomous rack 200 will now be presented. In certain embodiments, the cool rack cooling fluid from the liquid cooling source 110 may enter the rack fluid conduit 103 of the autonomous rack 200 between a temperature range of 25° C. to 30° C., for example 27° C. The cool rack cooling fluid 111 is directed through the at least one air-to-liquid heat exchanger 112 in which thermal energy is transferred to the cool rack cooling fluid 111, raising the temperature to a temperature between 33° C. and 38° C., for example to 35° C. The warm rack cooling fluid 113 is forwarded into the at least one cooling module 108 in which thermal energy is transferred from the higher temperature IC cooling fluid to the warm rack cooling fluid 113, raising the temperature to a temperature between 40° C. and 45° C., for example 42° C. The warmer rack cooling fluid 115 is directed through the one or more liquid cooling blocks 118A-118N and corresponding one or more electronic processing assemblies 120A-120N, in which thermal energy is transferred to the warmer rack cooling fluid 115, further raising the temperature to a temperature between 60° C. and 65° C., for example to 62° C., completing the first fluid circuit 104 where the warmest rack cooling fluid 117 is returned to the liquid source 110 via the outlet 109. Thus, the autonomous rack 200 configuration results in an ideal delta temperature, for example a temperature of 35° C., between the inlet 107 and the outlet 109 of the first fluid circuit 104. In some embodiments, the warmest rack cooling fluid 117 may be conducted in areas where heating is beneficial (e.g. offices) such that thermal energy is used for heating purposes. Additionally, cooling the fluid from 62° C. to 27° C., for example, is easier than cooling the fluid from 30° C. to 25° C. Indeed, it has been measured that an air flow on a heat exchanger, as well as a rotation speed of a pump for conducting the rack cooling fluid, may be divided by 2 or even 3 times between these two illustrative situations. This allows for a generic cooling system to be used which reduces capital expenditure costs, and requires less power consumption and water consumption, reducing operating expenses.

The IC rack 300, serviced by the hybrid cooling rack 10, is arranged in a closed loop configuration in which the IC rack cooling fluid 119 is circulated through the IC fluid conduit 105, forming the second cooling circuit 106. The closed loop configuration provides the benefit of maintaining the high quality of the IC rack cooling fluid 119. The IC rack cooling fluid 119 may be a dielectric liquid or a non-dielectric liquid, for example and without limitation, water, glycol, oil, or a combination thereof. In this embodiment, the IC cooling fluid is water.

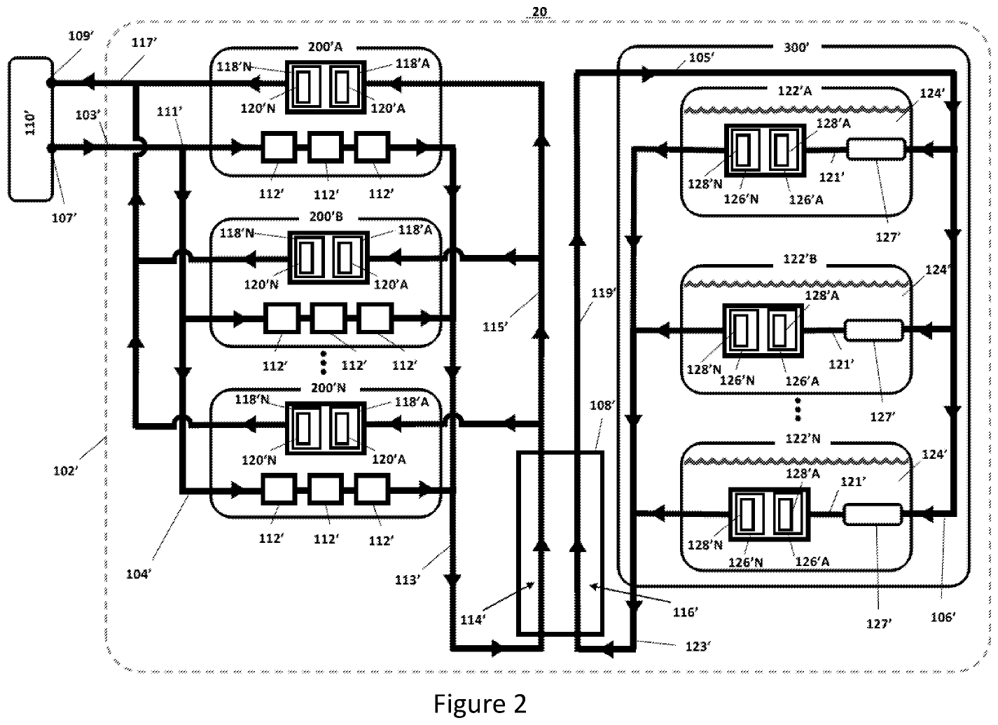

The IC rack 300 includes one or more liquid cooling blocks 126A-126N which are in direct thermal contact with corresponding electronic processing assemblies 128A-128N. The arrangement of the one or more liquid cooling blocks 126A-126N and one or more electronic processing assemblies 128A-128N are submerged in the dielectric immersion cooling fluid of the immersion casing 122. Each of the one or more liquid cooling blocks 126A-126N include an internal fluid conduit (not shown) for directing the IC rack cooling fluid 119 through the one or more liquid cooling blocks 126A-126N. In certain embodiments, the IC rack 300 includes a plurality of the one or more liquid cooling blocks 126A-126N and the one or more electronic processing assemblies 128A-128N arrangements positioned within a single immersion bath housing the immersion fluid 124 (not shown). The plurality of the one or more liquid cooling blocks 126A-126N and the one or more electronic processing assemblies 128A-128N arrangements may be fluidly connected in series, or fluidly connected in parallel, or a combination thereof. In an alternative embodiment, the IC rack 300 includes a plurality of immersion casings where each of the immersion casings houses an arrangement of the one or more liquid cooling blocks 126A-126N and the one or more electronic processing assemblies 128A-128N submerged in the immersion fluid 124 (for example, seen in FIG. 2).

The IC rack 300 may further includes a cooling device 127 positioned upstream from the one or more liquid cooling blocks 126A-126N and the one or more electronic processing assemblies 128A-128N arrangement. The cooling device 127 is submerged within the immersion fluid 124 such that thermal energy is transferred from the immersion fluid 124 to the IC rack cooling fluid 119. In certain embodiments, the cooling device 127 is a finned heat exchanger submerged in the immersion fluid 124. In some alternative embodiments, the cooling device is 127 is a serpentine convection coil The IC rack cooling fluid 119 flows through the cooling device 127 and thermal energy is transferred from the immersion fluid 124 to the IC rack cooling fluid 119, lowering the temperature of the immersion fluid 124. As a result, the temperature of the IC rack cooling fluid 119 is raised and may now be referred to as “warm IC rack cooling fluid 121”.

The warm IC cooling fluid 121 flows through the one or more liquid cooling blocks 126A-126N, in which thermal energy is transferred from the one or more electronic processing assemblies 120A-120N. As a result, the temperature of the warm IC rack cooling fluid 121 is raised and may now be referred to as “warmer IC rack cooling fluid 123”.

The warmer IC rack cooling fluid 123 is directed from the arrangement of the one or more liquid cooling blocks 126A-126N and the one or more electronic processing assemblies 128A-128N to the at least one cooling module 108, assembled with the autonomous rack 200 and configured to transfer thermal energy between the rack fluid conduit 103 of the first cooling circuit 104 and the IC fluid conduit 105 of the second cooling circuit 106. As previously described, the warm IC rack cooling fluid 121 flows through the second side 116 of the at least one cooling module 108 via an internal conduit (not shown). In this embodiment, the warmer IC cooling fluid 123 has a higher temperature than the warm rack cooling fluid 113. As such, thermal energy is transferred from the warmer IC cooling fluid 123 to the (cooler) warm rack cooling fluid 113, raising the temperature of the warm rack cooling fluid 113. The transfer of thermal energy from the warmer IC cooling fluid 123 cools the warmer IC cooling fluid 123 which may further be referred to as “IC cooling fluid 119”.

Exemplary temperatures along the fluid flow path of the IC rack 300 will now be presented. The IC rack cooling fluid 119 flows through the cooling device 127 between a temperature range of 43° C. to 48° C., for example 43° C. Thermal energy is transferred from the immersion fluid 124 to the IC rack cooling fluid 119, raising the temperature to a temperature between 63° C. to 68° C., for example 63° C. The warm IC rack cooling fluid 121 flows through the one or more liquid cooling blocks 126A-126N and the one or more electronic processing assemblies 128A-128N, raising the temperature to a temperature between 43° C. to 48° C., for example 43° C. Thermal energy is transferred to the warm IC rack cooling fluid 121, raising the temperature to a temperature between 50° C. to 60° C., for example to 55° C. The warmer IC rack cooling fluid 123 is directed through the at least one cooling module 108 where thermal energy is transferred from the warmer IC rack cooling fluid 123 to the warm rack cooling fluid 113, cooling the warmer IC rack cooling fluid 121 to a temperature between 43° C. and 48° C., for example to 43° C., which is then recirculated through the second fluid circuit 106. These exemplary temperatures and temperature ranges provide better cooling efficiency and heat recovery without overheating the equipment.

It is to be noted that the fluid conduits 103, 105 which make up the first fluid circuit 104 of the autonomous rack 200 and the second fluid circuit 106 of the IC rack 300 may embody any suitable piping, tubing, conduit, or other sealed conveyance structures capable of effectively transferring and distributing fluids and may also consist of metal, rubber, or plastic materials or any combination thereof.

As discussed above regarding the autonomous rack 200, the liquid cooling source 106 provides cool rack cooling fluid to the autonomous rack 200 configuration. In an alternative embodiment, the liquid cooling source 106 may correspond to an output of a heat exchanger, such as a dry cooler, which is configured to receive the warmest rack cooling fluid 117 and expel thermal energy thereof to provide the cool rack cooling fluid 111.

Furthermore, as previously described, the at least one air-to-liquid heat exchanger 112 may comprise a plurality of air-to-liquid heat exchangers 112 fluidly connected in series. It is contemplated, in an alternative embodiment, that the plurality of air-to-liquid heat exchangers 112 may be fluidly connected in parallel with one another. In a further alternative embodiment, some of the plurality of air-to-liquid heat exchangers 112 may be connected in series while some of the plurality of air-to-liquid heat exchangers 112 may be connected in parallel.

It is further contemplated that the air-to-liquid heat exchanger 112 may be positioned with respect to the one or more liquid cooling blocks 118A-118N and one or more electronic processing assemblies 120A-120N arrangement. In some embodiments, the air-to-liquid heat exchanger 112 may be fluidly connected in series with the one or more liquid cooling blocks 118A-118N and one or more electronic processing assemblies 120A-120N arrangement. In an alternative embodiment, the air-to-liquid heat exchanger 112 may be fluidly connected in parallel with the one or more liquid cooling blocks 118A-118N and one or more electronic processing assemblies 120A-120N arrangement.

It is contemplated, in another alternative embodiment, that the at least one cooling module 108 may be assembled with the IC rack 300 instead of the autonomous rack 200. It is further contemplated that the at least one cooling module 108 may be arranged separate from the autonomous rack 200 and the IC rack 300.

It is further noted that the at least one cooling module 108 of the exemplary autonomous rack 200 configuration may include two pumps and two plate heat exchangers, where one pump is fluidly connected in series with one of the plate heat exchangers. It is appreciated that a benefit of utilizing at least one cooling module 108 with at least one pump provides a distribution of pressure drop effect between the liquid source 110 and the at least one cooling module 108. Specifically, water pressure requirements are split between the pump of the liquid source 110 and the pump of the at least one cooling module 108 within the autonomous rack 200. The use of multiple pumps, instead of a single pump, within the datacenter enables a smaller carbon emission footprint, reducing the capital expenditure costs, and enables easier control of fluid flow within the datacenter, reducing operating expenses.

In a further alternative embodiment, the at least one cooling module 108 may solely comprise at least one plate heat exchanger.

As discussed above, the one or more liquid cooling blocks 118A-118N and one or more electronic processing assemblies 120A-120N are positioned downstream from the at least one cooling module 108. However, it is contemplated, in an alternative embodiment, that the one or more liquid cooling blocks 118A-118N and one or more electronic processing assemblies 120A-120N may instead be positioned upstream from the at least one cooling module 108. In this embodiment, the warm rack cooling fluid 113 is forwarded from the at least one air-to-liquid heat exchanger 112 to the one or more liquid cooling blocks 118A-118N and one or more electronic processing assemblies 120A-120N arrangement. Thermal energy is transferred from the one or more electronic processing assemblies 120A-120N to the warm rack cooling fluid 113, raising the temperature of the warm rack cooling fluid 113 which may be referred to as “warmer rack cooling fluid 115”. The warmer rack cooling fluid 115 is then directed through the first side 114 of the at least one cooling module 108. As previously described, thermal energy is transferred from the higher temperature IC rack cooling fluid to warmer rack cooling fluid 115, raising the temperature of the warmer rack cooling fluid 115 which may be referred to as “warmest rack cooling fluid 117”. The warmest rack cooling fluid 117 is then forwarded to the liquid cooling source 110 via the outlet 109.

As previously described, with regard to the IC rack 300 configuration, the second fluid circuit 106 is a closed loop configuration in which the IC rack cooling fluid 119 is circulated. It should be appreciated that, in an alternative embodiment, a semi-open loop configuration may be utilized. More specifically, the IC rack 300 configuration may receive and discharge the IC rack cooling fluid 119 from a cool IC rack liquid source, for example a reservoir.

As previously mentioned, the cooling device 127 of the IC rack 300 may be a serpentine convection coil which is submerged in the immersion fluid 124 of the immersion casing 122. More specifically, the serpentine convection coil may be positioned upstream from the one or more liquid cooling blocks 126A-126N and one or more electronic processing assemblies 128A-128N arrangement. The serpentine convection coil is structured with multiple hollow channel coils configured to receive and internally channel the IC rack cooling fluid. The IC rack cooling fluid enters the serpentine convection coil and thermal energy is transferred from the ambient immersion fluid 124, reducing the temperature of the immersion fluid 124 and raising the temperature of the IC rack cooling fluid. It is further contemplated that the cooling device 127 comprises a combination of a serpentine convection coil and a finned heat exchanger. The serpentine convection coil and finned heat exchanger may be fluidly connected in series with one another or, in an alternative embodiment, may be fluidly connected in parallel. It is appreciated that the serpentine convection coil may be positioned either upstream or downstream from the finned heat exchanger.

In some embodiments, the hybrid cooling arrangement 10 may implement a liquid distribution infrastructure comprising a flow controller, flow distribution channel segments, temperature sensors, and flow control valves to service the liquid cooling needs of both the autonomous rack 200 and IC rack 300 configurations. In certain embodiments, flow control valves may comprise solenoid valves to refine control and provide load re-partition. For example, it is contemplated that a temperature sensor may be positioned along the second fluid circuit 106 upstream from the cooling module 108 such that the temperature of the IC rack cooling fluid is detected before entering the cooling module 108. A solenoid valve may be positioned on the first cooling circuit 104, before the cooling module 108, to modulate the flow of the rack cooling fluid into the cooling module 108 in response to the detected temperature of the IC rack cooling fluid. Thus, controlling the cooling system of the autonomous rack 200 and the IC rack 300 to avoid overheating, optimize heat recovery, and maximize the delta temperature based on the load of each of the racks 200, 300.

With reference now to FIG. 2, a functional block diagram of an alternative hybrid cooling arrangement 20 is depicted. The hybrid cooling arrangement 20 differs from the hybrid cooling arrangement 10 of FIG. 1 in that a plurality of autonomous racks 200′A-200′N are provided, and a single IC rack 300′ with a plurality of immersion casings 122′A-122′N are provided in a datacenter rack assembly 102′. Each autonomous rack of the plurality of autonomous racks 200′A-200′N may correspond to the autonomous rack 200 of FIG. 1. The IC rack 300′ may correspond to the IC rack 300 of FIG. 1. The datacenter rack assembly 102′ may correspond to the datacenter rack assembly 102 of FIG. 1.

The hybrid cooling arrangement 20 services the plurality of autonomous racks 200′A-200′N and the IC rack 300′, with each of the plurality autonomous racks 200′A-200′N being fluidly isolated from each of the immersion casings 122′A-122′N of the IC rack 300′. In other words, as with FIG. 1, the plurality of autonomous racks 200′A-200′N include the rack fluid conduit 103′, forming the first cooling circuit 104′ and the IC rack 300′ includes an IC fluid conduit 105′, forming a second cooling circuit 106′. The rack fluid conduit 103′, the first cooling circuit 104′, the IC fluid conduit 105′, and the second cooling circuit 106′, may correspond to the rack fluid conduit 103, the first cooling circuit 104, the IC fluid conduit 105, and the second cooling circuit 106 of FIG. 1. The first cooling circuit 104′ is not fluidly connected to the second cooling circuit 106′. Rather, the plurality of autonomous racks 200′A-200′N and the IC rack 300′ are thermally connected via a cooling module 108′ such that thermal energy can be transferred between the rack fluid conduit 103′ of the first cooling circuit 104′ of the plurality of autonomous racks 200′A-200′N and the IC fluid conduit 105′ of the second cooling circuit 106′ of the IC rack 300′. It is appreciated that the cooling module 108′ may correspond to the at least one cooling module 108 of FIG. 1.

In this embodiment, the plurality of autonomous racks 200′A-200′N are fluidly connected in parallel to one another and the rack fluid conduit 103′ is configured to receive a cool rack cooling fluid 111′ from a liquid source 110′ via an inlet 107′. It is noted that the cool rack cooling fluid 111′, liquid source 110′, and the inlet 107′ may correspond to the cool rack cooling fluid 111, the liquid source 110, and the inlet 107 of FIG. 1. As previously described, the liquid source 110′ may be a facility with the received cool rack cooling fluid 111′ being water. Each of the plurality of autonomous racks 200′A-200′N include at least one air-to-liquid heat exchanger 112′. It should be noted that the at least one air-to-liquid heat exchanger 112′ may be configured as any of the previously described embodiments including the at least one air-to-liquid heat exchanger 112 of FIG. 1. The at least one heat exchanger 112′ receives the cool rack cooling fluid 111′ which flows through internal fluid conduits (not shown) of the at least one heat exchanger 112′. Thermal energy of ambient air is transferred to the cool rack cooling fluid 111′ and cool air is expelled. The transfer of thermal energy to the cool rack cooling fluid 111′ raises the temperature of the cool rack cooling fluid which may be referred to as “warm rack cooling fluid 113”. It is noted that the warm rack cooling fluid 113′ may correspond to the warm rack cooling fluid 113 of FIG. 1.

As previously described, the warm rack cooling fluid is forwarded to a first side 114′ of the cooling module 108′ which thermally connects the rack fluid conduit 103′ of the first cooling circuit 104′ with the IC fluid conduit 105′ of the second cooling circuit 106′ for the transfer of thermal energy therebetween. It is appreciated that the first side 114′ may correspond to the first side 114 of FIG. 1. In certain embodiments, the thermal energy of the higher temperature IC rack cooling fluid is transferred to the warm rack cooling fluid 113′ within the cooling module 108′, cooling the IC rack cooling fluid. The transfer of thermal energy to the warm rack cooling fluid 113′ raises the temperature of the warm rack cooling fluid 113′ which may further be referred to as “warmer rack cooling fluid 115′”. The warmer rack cooling fluid 115′ may correspond with the warmer rack cooling fluid 115 of FIG. 1.

In this embodiment, the cooling module 108′ is arranged separate from the plurality of autonomous racks 200′A-200′N and the IC rack 300′. However, it is contemplated that the cooling module 108′ may be assembled with any one of the plurality of autonomous racks 200′A-200′N or with the IC rack 300′.

The warmer rack cooling fluid 115′ is directed from the cooling module 108′ and forwarded to one or more liquid cooling blocks 118′A-118′N which are in direct thermal contact with corresponding electronic processing assemblies 120′A-120′N. It is contemplated that the arrangement of the one or more liquid cooling blocks 118′A-118′N and the one or more electronic processing assemblies 120′A-120′N may be configured as any of the previously described embodiments, including the one or more liquid cooling blocks 118A-118N and one or more electronic processing assemblies 120A-120N of FIG. 1. Thermal energy is transferred from the one or more electronic processing assemblies 120′A-120′N to the warmer rack cooling fluid 115′, raising the temperature of the warmer rack cooling fluid 115′ which may further be referred to as “warmest rack cooling fluid 117”. It is contemplated that the warmest rack cooling fluid 117′ may correspond to the warmest rack cooling fluid 117 of FIG. 1. The warmest rack cooling fluid 117′ is then forwarded to the liquid cooling source 110′ via an outlet 109′. The outlet 109′ may be configured as the outlet 109 of FIG. 1.

An exemplary flow path of the rack cooling fluid through first cooling circuit 104′ of the plurality of autonomous racks 200′A-200′N will now be described. The rack cooling fluid enters the first fluid circuit 104′ through the inlet 107′. The fluid flows through the rack fluid conduit 103′ of the plurality of autonomous racks 200′A-200′N. In FIG. 1, the autonomous racks 200′A-200′N are fluidly connected in parallel, as such, the fluid splits and flows through each of the autonomous racks 200′A-200′N in parallel. In each of the autonomous racks 200′A-200′N, the fluid flows through at least one air-to-liquid heat exchanger 112′. The fluid is then directed through the at least one cooling module 108′. Upon exiting the at least one cooling module 108′, the fluid is, again, split such that it flows through each of the autonomous racks 200′A-200′N in parallel. Specifically, the fluid is advanced through the one or more liquid cooling blocks 118′A-118′N and the one or more electronic processing assemblies 120′A-120′N arrangement, and eventually returns to the liquid source 110′ via the outlet 109′.

Regarding the IC rack 300′, each of the plurality of immersion casings 122′A-122′N are fluidly connected in parallel with one another in a closed loop configuration which circulates an IC rack cooling fluid 119′. The IC rack cooling fluid 119′ may correspond to the IC rack cooling fluid 119 of FIG. 1 and may be a dielectric liquid or a non-dielectric liquid, for example and without limitation, water, glycol, oil, or a combination thereof. In this embodiment, the IC cooling fluid 119′ is water.

Each of the plurality of immersion casings 122′A-122′N houses an immersion cooling fluid 124′, for example a dielectric immersion cooling fluid. The immersion cooling fluid 124′ may correspond to the immersion cooling fluid 124 of FIG. 1. Each of the immersion casings 122′A-122′N of the IC rack 300′ includes one or more liquid cooling blocks 126′A-126′N which are in direct thermal contact with corresponding electronic processing assemblies 128′A-128′N. The arrangement of the one or more liquid cooling blocks 126′A-126′N and one or more electronic processing assemblies 128′A-128′N are submerged in the dielectric immersion cooling fluid of the immersion casing 122′A-112′N. It is appreciated there may be a plurality of the one or more liquid cooling blocks 126′A-126′N and one or more electronic processing assemblies 128′A-128′N arrangements in each of the immersion casings 122′A-122′N and that the one or more liquid cooling blocks 126′A-126′N and one or more electronic processing assemblies 128′A-128′N may be configured in any of the previously described embodiments including the one or more liquid cooling blocks 126A-126N and one or more processing assemblies 128A-128N of FIG. 1. Each of the immersion casings 122′A-122′N further includes a cooling device 127′ submerged in the immersion fluid 124′ and positioned upstream from the arrangement of the one or more liquid cooling blocks 126′A-126′N and one or more electronic processing assemblies 128′A-128′N. The cooling device 127′ may correspond to the cooling device 127 of any of the previously described embodiments, including the cooling device 127 of FIG. 1.

The IC rack cooling fluid 119′ flows through the cooling device 127′ and thermal energy is transferred from the immersion fluid 124′ to the IC rack cooling fluid 119′, lowering the temperature of the immersion fluid 124′. As a result, the temperature of the IC rack cooling fluid 119′ is raised and may now be referred to as “warm IC rack cooling fluid 121”. The warm IC rack cooling fluid 121′ may correspond to the warm IC rack cooling fluid 121 of FIG. 1.

The warm IC rack cooling fluid 121′ flows through the one or more liquid cooling blocks 126′A-126′N, in which thermal energy is transferred from the one or more electronic processing assemblies 120′A-120′N. As a result, the temperature of the warm IC rack cooling fluid 121′ is raised and may now be referred to as “warmer IC rack cooling fluid 123”. The warmer IC rack cooling fluid 123′ may correspond to the warmer IC cooling rack fluid 123 of FIG. 1.

As previously described, the warmer IC rack cooling fluid 123′ is directed from the arrangement of the one or more liquid cooling blocks 126′A-126′N and the one or more electronic processing assemblies 128′A-128′N to the second side 116′ of the cooling module 108′. It is noted that the second side 116′ of the cooling module 108′ may correspond to the second side 116 of the at least one cooling module 108 of FIG. 1. Thermal energy is transferred from the warmer IC cooling fluid 123′ to the (cooler) warm rack cooling fluid 113′, raising the temperature of the warm rack cooling fluid 113′ (as previously described). The transfer of thermal energy from the warmer IC cooling fluid 123′ cools the warmer IC cooling fluid 123′ which may further be referred to as “IC cooling fluid 119′”.

An exemplary flow path of the IC rack cooling fluid will now be described. The rack cooling fluid is circulated in a closed loop configuration. The fluid flows through the rack fluid conduit 105′ of the IC rack 300′. In FIG. 2, the IC rack 300′ is configured to have the plurality of immersion casings 122′A-122′N fluidly connected in parallel, as such, the fluid splits and flows through each of the immersion casings 122′A-122′N in parallel. In each of the immersion casings 122′A-122′N, the fluid flows through the cooling device 127′. The fluid is then directed through the one or more liquid cooling blocks 118′A-118′N and the one or more electronic processing assemblies 120′A-120′N arrangement housed within each of the immersion casings 122′A-122′N. The fluid is then advanced through the at least one cooling module 108′ and recirculated through the IC rack 300′ configuration.

It is contemplated that instead of a plurality of immersion casings 122′A-122′N, the IC rack 300′ may include a plurality of one or more liquid cooling blocks 126′A-126′N and the one or more electronic processing assemblies 120′A-120′N arrangements housed within an immersion bath (not shown). In a further alternative embodiment, the IC rack 300′ may have a combination of immersion casings 122′A-122′N and an immersion bath (not shown).

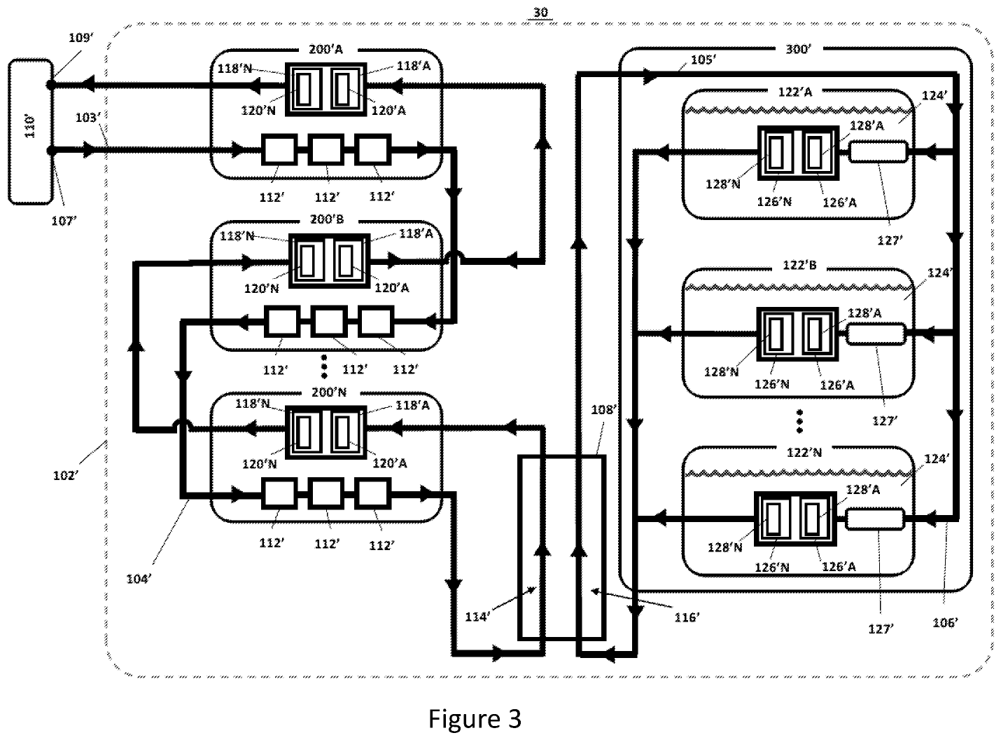

An alternative hybrid cooling arrangement 30 is depicted in FIG. 3. It is appreciated that the plurality of autonomous racks 200′A-200′N may be fluidly connected to one another in series with one another. It is further contemplated that some of the plurality of autonomous racks 200′A-200′N may be fluidly connected in series and some of the plurality of autonomous racks 200A′-200′N may be connected in parallel (not shown).

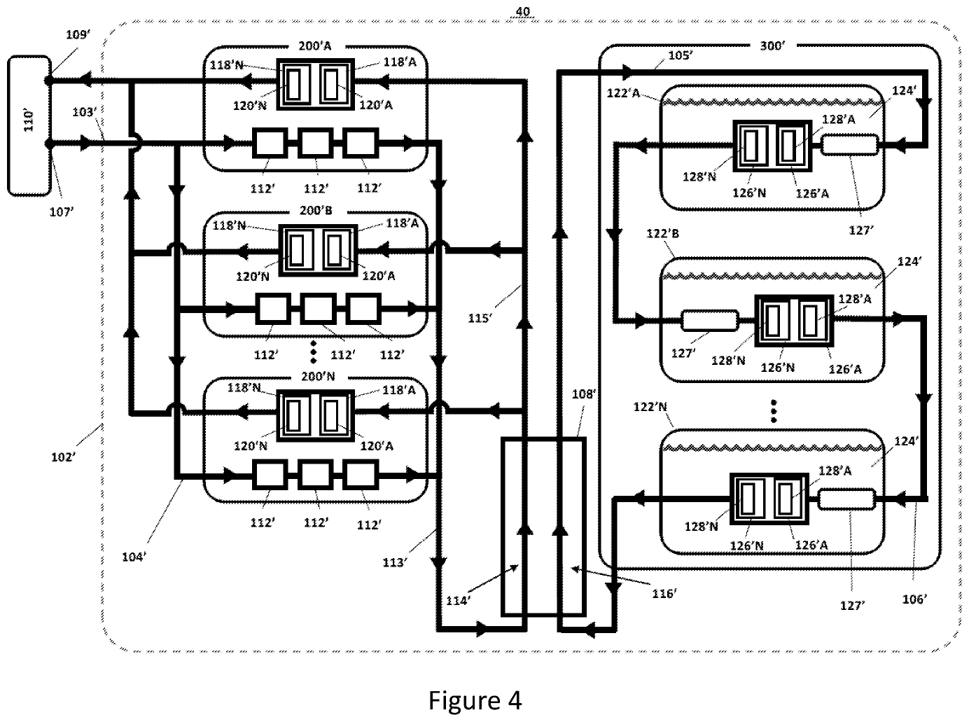

As previously described, the plurality of immersion casings 122′A-122′N of the IC rack 300′ may be fluidly connected to one another in parallel. However, as depicted in FIG. 4, the hybrid cooling arrangement 40 may include the immersion casings 122′A-122′N being fluidly connected to one another in series. Alternatively, some of the plurality of immersion casings 122′A-122′N may be fluidly connected in series and some of the plurality of immersion casings 122′A-122′N may be fluidly connected in parallel (not shown).

It is contemplated, in an alternative embodiment, that the hybrid cooling arrangement (not shown) may include a single autonomous rack and a plurality of IC racks thermally connected via a cooling module, such as the cooling module 108 or the cooling module 108′. It is noted that the autonomous rack, each of the plurality of IC racks, and the cooling module of this alternative embodiment may be configured as any of the autonomous rack, the IC racks, and the cooling module in the previously described embodiments.

As presented herein, the disclosed embodiments provide hybrid cooling arrangements 10, 20, 30, 40 that provide thermally integrative cooling infrastructure to accommodate the cooling needs of the autonomous rack 200, 200′A-200′N and the IC rack 300, 300′ configurations coexisting within a datacenter rack assembly 102, 102′. The hybrid cooling arrangement 10, 20, 30, 40 provides at least one cooling module 108, 108′ configured to thermally connect the autonomous rack 200, 200′A-200′N and IC rack 300, 300′, thereby enabling the transfer of thermal energy between the two.

The disclosed embodiments of the hybrid cooling arrangement 10, 20, 30, 40 provide various benefits including, but not limited to, an increased delta temperature between an inlet 107, 107′ and outlet 109, 109′ of the first fluid circuit 104, 104′ within the autonomous rack 200, 200′A-200′N. This increased in delta temperature has a significant impact on the reduction of datacenter operating expenses and capital expenditures. Additionally, the disclosed configuration of the autonomous rack 200, 200′A-200′N allows for a distribution of pressure drop effect between the cooling liquid source 110, 110′ and the at least one cooling module 108, 108′. The hybrid cooling arrangement 10, 20, 30, 40 requires less pumping and no sophisticated pumps, ultimately reducing costs. Furthermore, as the IC rack 300, 300′ configuration is fluidly isolated, the quality of the IC rack cooling fluid can be preserved.

In view of the various disclosures directed to a hybrid cooling arrangement for servicing both autonomous racks and IC racks deployed within a datacenter rack assembly, it will be understood that, although the embodiments presented herein have been described with reference to specific features and structures, it is clear that various modifications and combinations may be made without departing from such disclosures. The specification and drawings are, accordingly, to be regarded simply as an illustration of the discussed implementations or embodiments and their principles as defined by the appended claims, and are contemplated to cover any and all modifications, variations, combinations or equivalents that fall within the scope of the present disclosure.

What is claimed is:

1. A rack assembly comprising:
a cooling module for liquid-to-liquid cooling;
a rack comprising:
a rack cooling block configured to cool a rack electronic processing assembly when the rack electronic processing assembly is placed in contact with the rack cooling block; and,
a rack fluid conduit configured to circulate a first cooling fluid through the rack cooling block and the cooling module;
and,
an immersion cooling (IC) rack comprising:
a dielectric immersion cooling fluid;
an IC cooling block immersed in the dielectric immersion cooling fluid and configured to cool an IC electronic processing assembly when the IC electronic processing assembly is placed in contact with the IC cooling block; and,
an IC fluid conduit configured to circulate a second cooling fluid through the IC cooling block and the cooling module;
wherein the rack and the immersion cooling rack are thermally connected via the cooling module such that thermal energy can be transferred between the IC fluid conduit and the rack fluid conduit within the cooling module.

2. The rack assembly of claim 1, wherein the IC rack further comprises:
a plurality of immersion casings fluidly connected in parallel with one another and configured to house the dielectric immersion cooling fluid;
wherein the IC cooling block comprises a plurality of IC cooling blocks; and,
each of the plurality of IC cooling blocks are housed within each of the plurality of immersion casings.

3. The rack assembly of claim 1, wherein the IC rack further comprises:
a plurality of IC racks immersion casings fluidly connected in series with one another and configured to house the dielectric immersion cooling fluid;
wherein the IC cooling block comprises a plurality of IC cooling blocks; and,
each of the plurality of IC cooling blocks are housed within each of the plurality of immersion casings.

4. The rack assembly of claim 1, wherein the rack further comprises an air-to-liquid heat exchanger configured to receive the first cooling fluid via the rack fluid conduit such that thermal energy of the first cooling fluid is transferred to ambient air.

5. The rack assembly of claim 1, wherein the cooling module comprises a cooling module pump and a liquid-to-liquid heat exchanger, wherein the cooling module pump is fluidly connected in series to the liquid-to-liquid heat exchanger.

6. The rack assembly of claim 1, wherein the rack cooling block is fluidly connected downstream from the cooling module, or wherein the rack cooling block is fluidly connected upstream from the cooling module.

7. The rack assembly of claim 1, wherein the rack fluid conduit and the IC fluid conduit are fluidly isolated from one another.

8. The rack assembly of any one of claim 1, wherein thermal energy is transferred from the IC fluid conduit to the rack fluid conduit within the cooling module.

9. The rack assembly of claim 1, wherein the rack comprises a plurality of racks fluidly connected in parallel with one another.

10. The rack assembly of claim 1, wherein the rack comprises a plurality of racks fluidly connected in series with one another.

11. The rack assembly of claim 1, wherein the rack further comprises the rack electronic processing assembly, and wherein the IC rack further comprises the IC electronic processing assembly.

12. The rack assembly of claim 1, wherein the IC rack further comprises a cooling device.

13. The rack assembly of claim 1, wherein the rack fluid circuit comprises an inlet and an outlet and wherein a temperature difference of the first cooling fluid between the inlet and the outlet is greater than 20° C.

14. The rack assembly of claim 1, wherein the rack further comprises a plurality of racks, each rack comprising a distinct rack cooling block and a distinct air-to-liquid heat exchanger and wherein the distinct rack cooling blocks are connected in series with one another and the distinct air-to-liquid heat exchangers are connected in series with one another.

15. The rack assembly of claim 1, wherein the rack further comprises a plurality of racks, each rack comprising a distinct rack cooling block and a distinct air-to-liquid heat exchanger and wherein the distinct rack cooling blocks are connected in parallel with one another and the distinct air-to-liquid heat exchangers are connected in parallel with one another.
